(19) United States
(12) Patent Application Publication
(10) Pub. No.: US 2023/0236239 A1
(43) Pub. Date: Jul. 27, 2023

(54) GATE VOLTAGE DETERMINATION APPARATUS, GATE VOLTAGE DETERMINATION METHOD, GATE DRIVING CIRCUIT AND SEMICONDUCTOR CIRCUIT

(71) Applicant: FUJI ELECTRIC CO., LTD., Kanagawa (JP)

(72) Inventor: Naoki KUMAGAI, Matsumoto-city (JP)

(21) Appl. No.: 17/988,780

(22) Filed: Nov. 17, 2022

(30) Foreign Application Priority Data
Jan. 21, 2022 (JP) 2022-007969

(51) Int. Cl. G01R 31/26

(52) U.S. Cl. CPC G01R 31/2607; H01L 29/063

(57) ABSTRACT

Provided is a gate voltage determination apparatus of a MOS transistor having a gate electrode, a gate insulating film and a channel region, the gate voltage determination apparatus including: a characteristic acquisition unit configured to acquire current-voltage characteristics showing a relationship between a gate current flowing through the gate electrodes and a gate voltage when the gate voltage applied to the gate electrode is changed from a higher voltage side to a lower voltage side; and a voltage determination unit configured to determine, based on a value of the gate voltage at which the gate current shows a peak waveform in the current-voltage characteristics, an off-gate voltage to be applied to the gate electrode when turning off the MOS transistor.

The contents of the following Japanese patent application(s) are incorporated herein by reference:
NO. 2022 -007969 filed in JP on Jan. 21, 2022

### BACKGROUND

### 1. Technical Field

The present invention relates to a gate voltage determination apparatus, a gate voltage determination method, a gate driving circuit and a semiconductor circuit.

### 2. Related Art

Conventionally, a technique is known to apply a negative voltage to a gate electrode when turning a MOS transistor to an off-state (for example, refer to Patent Document 1).

Patent Document 1: Japanese Patent Application Publication No. 2019-161079

### BRIEF DESCRIPTION OF THE DRAWINGS

FIG. 1 illustrates a block diagram showing an example of a gate voltage determination apparatus 100 according to one embodiment of the present invention.

FIG. 2 illustrates a cross-sectional view showing an overview of a MOS transistor 200.

FIG. 3 illustrates an example of current-voltage characteristics acquired by a characteristic acquisition unit 104.

FIG. 4 illustrates an example of a gate voltage waveform when measuring the current-voltage characteristics.

FIG. 5 illustrates a hole injection start voltage V_{S}.

FIG. 6 illustrates an example of the gate voltage applied to the MOS transistor 200.

FIG. 7 illustrates another determination method of an effective hole injection start voltage V_{E}.

FIG. 8 illustrates fluctuation of a threshold voltage Vth.

FIG. 9 illustrates which peak waveform 154 is used to determine the hole injection start voltage when a plurality of peak waveforms 154 are included in the current-voltage characteristics (first characteristics 152).

FIG. 10 illustrates a flowchart showing an overview of a gate voltage determination method of the MOS transistor 200.

FIG. 11 illustrates a block diagram showing an overview of a semiconductor circuit 300 according to one embodiment of the present invention.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention.

Unless otherwise stated, SI unit system is used as unit system herein. When referred to as “same” or “equal” in this specification, it may include a case where there is an error caused by production variation or the like. The error is, for example, within 10%.

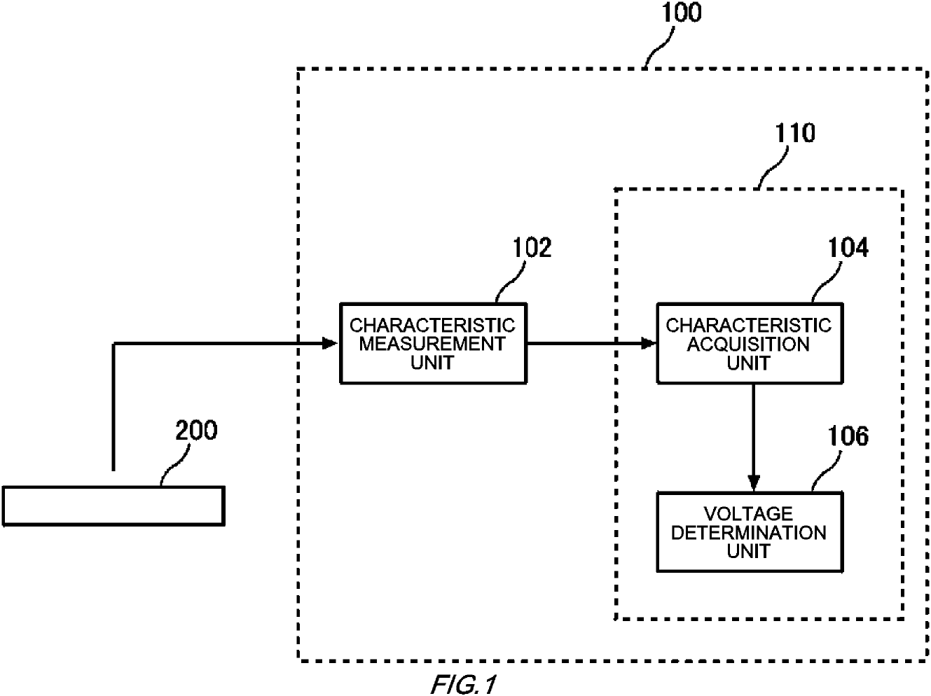

FIG. 1 illustrates a block diagram showing an example of a gate voltage determination apparatus 100 according to one embodiment of the present invention. The gate voltage determination apparatus 100 determines a value of a voltage to be applied to a gate electrode (referred to as an off-gate voltage in the present specification) when turning a MOS transistor 200 to an off-state.

The MOS transistor 200 has a gate electrode, a gate insulating film and a channel region. The MOS transistor 200 is a SiC-MOSFET formed on a silicon carbide (SiC) substrate as an example. The MOS transistor 200 may also be a MOSFET formed on a semiconductor substrate of another composition. The MOS transistor 200 may be formed on a compound semiconductor substrate such as gallium nitride (GaN).

The gate voltage determination apparatus 100 has a characteristic measurement unit 102 and an information processing apparatus 110. The characteristic measurement unit 102 measures characteristics of the MOS transistor 200. The MOS transistor 200 measured by the characteristic measurement unit 102 may be the same individual as the MOS transistor that is the target for setting the off-gate voltage, or may be another individual with a similar structure. The characteristic measurement unit 102 may measure an average value of the characteristics of a plurality of MOS transistors 200 with the similar structure.

The characteristic measurement unit 102 has a means that can measure the characteristics of the MOS transistor 200. For example, the characteristic measurement unit 102 has a means for applying a gate voltage to the MOS transistor 200, a means for measuring a drain current and a gate current of the MOS transistor 200 and so on. The characteristic measurement unit 102 may also have a means for measuring luminescence in the MOS transistor 200. In the present example, the characteristic measurement unit 102 measures current-voltage characteristics showing a relationship between the gate current flowing through the gate electrodes and the gate voltage when the gate voltage applied to the gate electrode of the MOS transistor 200 is changed from a higher voltage side to a lower voltage side. Details of the current-voltage characteristics are described below.

The information processing apparatus 110 calculates and processes a measurement result of the characteristic measurement unit 102. In the present example, although the gate voltage determination apparatus 100 includes the characteristic measurement unit 102, the gate voltage determination apparatus 100 may also receive the measurement result from an external characteristic measurement unit 102. In this case, the gate voltage determination apparatus 100 may not include the characteristic measurement unit 102.

The information processing apparatus 110 has a characteristic acquisition unit 104 and a voltage determination unit 106. The characteristic acquisition unit 104 acquires the characteristics of the MOS transistor 200 measured by the characteristic measurement unit 102. The voltage determination unit 106 determines the off-gate voltage of the MOS transistor 200 based on the characteristics of the MOS transistor 200 acquired by the characteristic acquisition unit 104. A determination method of the off-gate voltage is described below.

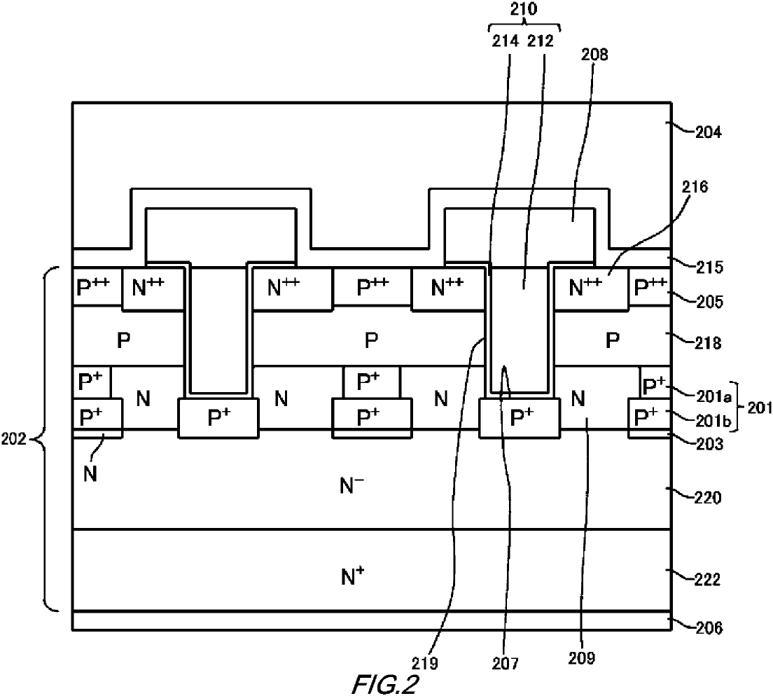

FIG. 2 illustrates a cross-sectional view showing an overview of the MOS transistor 200. The MOS transistor 200 has a semiconductor substrate 202, interlayer dielectric films 208, a source electrode 204 and a drain electrode 206. When the MOS transistor 200 is turned into an on-state, the drain current flows between the source electrode 204 and the drain electrode 206 via the semiconductor substrate 202.

In the present example, the source electrode 204 is provided via a barrier metal 215 on an upper surface of the semiconductor substrate 202, the drain electrode 206 is provided on a lower surface of the semiconductor substrate 202. In the present example, the MOS transistor 200 is a vertical-type apparatus with the drain current flowing between the upper surface and the lower surface of the semiconductor substrate 202. In another example, the source electrode 204 and the drain electrode 206 may both be provided on the upper surface of the semiconductor substrate 202. In this case, the MOS transistor 200 is a horizontal-type apparatus with current flowing in a direction along the upper surface of the semiconductor substrate 202. The barrier metal 215 is provided in order to prevent diffusion of metal atoms from the source electrode 204 to the gate electrode 212 side.

The semiconductor substrate 202 is a SiC substrate as an example. The semiconductor substrate 202 has a drift region 220 of an N⁻ type through which the drain current flows. Source regions 216 of an N⁺⁺ type are formed on the upper surface of the semiconductor substrate 202. Also, channel regions 218 of a P type and high concentration regions 209 of an N type are formed between the source regions 216 and the drift region 220.

Also, gate trench portions 210 are provided in the semiconductor substrate 202, passing through the source regions 216 and the channel regions 218 from the upper surface to the high concentration regions 209 of the N type. The gate trench portion 210 has a gate electrode 212 and a gate insulating film 214. The gate electrode 212 is formed of a conductive material such as polysilicon with added impurities. The gate electrode 212 is insulated from the source electrode 204 by the insulating film between layers 208. The gate insulating film 214 insulates the gate electrode 212 from the semiconductor substrate 202. The gate insulating film 214 is, for example, a silicon oxide film. The gate insulating film 214 is at least arranged between the gate electrode 212 and the channel regions 218. An interface between the gate insulating film 214 and the channel regions 218 is an interface 219. Upper sub-regions 201a of a P⁺ type are locally provided on an upper side inside the high concentration regions 209 of the N type. The upper sub-regions 201a of the P⁺ type are, for example, provided between the gate trench portions 210. Also, inside the high concentration regions 209 of the N type, lower sub-regions 201b of the P⁺ type are provided in contact with bottom portions 207 of the gate trench portions 210 and bottom portions of the upper sub-regions 201a of the P⁺ type. The lower sub-regions 201b of the P⁺ type in contact with the bottom portions 207 of the gate trench portions 210 are provided in positions facing the bottom portions 207 in a depth direction. The upper sub-regions 201a of the P⁺ type and the lower sub-regions 201b of the P⁺ type are combined to form sub-regions 201 of the P⁺ type. Also, inside the drift region 220, sub-regions 203 of the N type, with an impurity concentration higher than the drift region 220, may be provided in positions deeper than the lower sub-regions 201b of the P⁺ type between the gate trench portions 210. Contact regions 205 of a P⁺⁺ type are be selectively provided inside the upper surfaces of the channel regions 218. While, in the present example, the MOS transistor 200 is a trench-type apparatus in which the gate electrodes 212 and the gate insulating films 214 are embedded inside the semiconductor substrate 202, the MOS transistor 200 may also be a planar-type apparatus with the gate electrodes 212 and the gate insulating films 214 stacked on the upper surface of semiconductor substrate 202.

The gate voltage is applied to the gate electrode 212. When an on-gate voltage is applied to the gate electrode 212, a channel inverted into the N type is formed in the channel region 218 near the interface 219, and carriers flow between the source regions 216 and the drift regions 220.

A drain region 222 of an N⁺ type is provided on the lower surface of the semiconductor substrate 202. When a channel is formed on a surface of the channel region 218, current flows between the source regions 216 and the drain region 222. The MOS transistor 200 may be an IGBT in which a collector region of the P+ type is provided instead of the drain region 222.

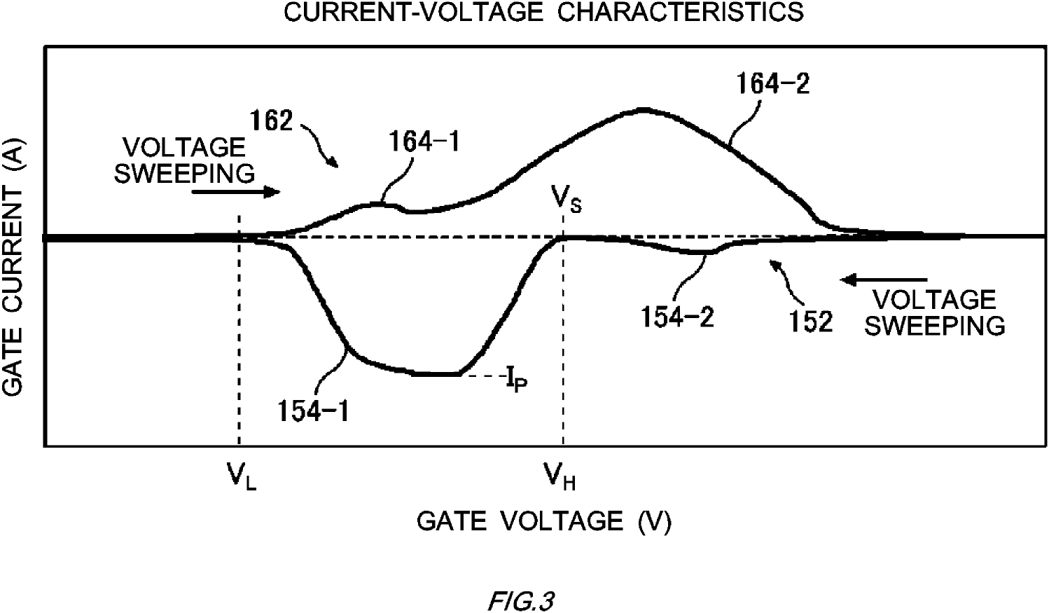

FIG. 3 illustrates an example of current-voltage characteristics acquired by the characteristic acquisition unit 104. The current-voltage characteristics are, for example, characteristics measured under room temperature (25° C.), but not limited thereto. In FIG. 3, a horizontal axis indicates the gate voltage, a vertical axis indicates the gate current. The current-voltage characteristics include first characteristics 152 showing a relationship between the gate current flowing through the gate electrodes and the gate voltage when the gate voltage applied to the gate electrode 212 is changed from the higher voltage side to the lower voltage side. The higher voltage side refers to a side where the value of the voltage is larger, and the lower voltage side refers to a side where the value of the voltage is smaller. Note that, a negative voltage shall be smaller than a positive voltage, even if its absolute value is larger. For a positive voltage, the side with a larger absolute value is the higher voltage side, and for a negative voltage, the side with a larger absolute value is the lower voltage side. In the present example, the on-gate voltage of the MOS transistor 200 is arranged on the higher voltage side than the off-gate voltage.

Note that, in the current-voltage characteristic diagram, the right side of the horizontal axis is the higher voltage side and the left side of the horizontal axis is the lower voltage side, unless otherwise particularly described. Also, the upper side of the vertical axis is a higher current side, the lower side of the vertical axis is a lower current side. The current-voltage characteristics may further include second characteristics 162 showing a relationship between the gate current flowing through the gate electrodes and the gate voltage when the gate voltage applied to the gate electrode 212 is changed from the lower voltage side to the higher voltage side,. In the present example, the current-voltage characteristics are typical characteristics for the case where the interface between the channel regions 218 and the gate insulating film 214 is an a-plane or m-plane, but are not limited thereto.

The first characteristics 152 include one or more peak waveforms 154. A peak waveform refers to a waveform in which the gate current fluctuates from an initial value (for example, 0A) in response to a gate voltage sweep, and then the gate current converges to the initial value. In the present example, the first characteristics 152 include a peak waveform 154-1 and a peak waveform 154-2. When the gate voltage is swept from the higher voltage side to the lower voltage side, electrons may be excited from shallow electron traps at the interface 219 between the channel regions 218 and the gate insulating film 214, and the gate current may flow. In this manner, the peak waveform 154-2 may be observed. The amplitude of the peak waveform 154-2 is typically relatively small.

When the gate voltage is further swept to the lower voltage side, holes in the channel region 218 overcome the potential barrier created by the depletion layer, then the holes are trapped in hole traps at the interface 219, or the holes recombine with the electrons trapped at the interface 219. In this manner, the peak waveform 154-1 is observed. The amplitude of the peak waveform 154-1 may be larger than that of the peak waveform 154-2. The gate voltage at which holes overcome the potential barrier and begin to be trapped in the hole traps at the interface 219 or begin to recombine with electrons in the electron traps at the interface 219 is used as a hole injection start voltage V_{S}. Of the gate voltages V_{H} and V_{L} at both ends of the peak waveform 154-1, the gate voltage V_{H} on the higher voltage side may be used as the hole injection start voltage V_{S}. The gate voltage at both ends of the peak waveform is the voltage at which the gate current begins to fluctuate from the initial value, or the voltage at which the gate current converges to the initial value. When the positions of both ends of the peak waveform are unclear, the positions, at which the value of current becomes ⅒ of the peak value I_{P} of the peak waveform, may be used as both ends of the peak waveform. Alternatively, the positions where the value of current becomes 1/100 of the peak value I_{P} may be used as both ends of the peak waveform.

In this manner, if the gate voltage is set too low, many holes are to be trapped in the hole traps at the interface 219. If many holes are trapped at the interface 219, the threshold voltage Vth when turning on the MOS transistor 200 will fluctuate.

Note that, the second characteristics 162 include one or more peak waveforms 164. In the present example, the second characteristics 162 include a peak waveform 164-1 and a peak waveform 164-2. When the gate voltage is swept from the lower voltage side to the higher voltage side, holes may be excited from shallow hole traps at the interface 219, and the gate current may flow. In this manner, the peak waveform 164-1 may be observed. The amplitude of the peak waveform 164-1 is relatively small.

When the gate voltage is further swept to the higher voltage side, electrons in the inversion layer (channel) of the channel region 218 recombine with holes in the hole traps at the interface 219, or are trapped in the electron traps at the interface 219. In this manner, the peak waveform 164-2 is observed. The amplitude of the peak waveform 164-2 may be larger than that of the peak waveform 164-1.

The voltage determination unit 106 determines the off-gate voltage to be applied to the gate electrode 212 when turning off the MOS transistor 200, based on the first characteristics 152 included in the current-voltage characteristics. More particularly, the voltage determination unit 106 determines the off-gate voltage based on the gate voltage value indicating the peak waveform 154-1 (in the present example, a value within a voltage range of V_{H} to V_{L}). Since the voltage at which a large amount of holes are trapped at the interface 219 can be estimated from the gate voltage of the peak waveform 154-1, the off-gate voltage at which the fluctuation of the threshold voltage Vth is suppressed can be determined. The voltage determination unit 106 may determine the off-gate voltage based on the hole injection start voltage V_{S}.

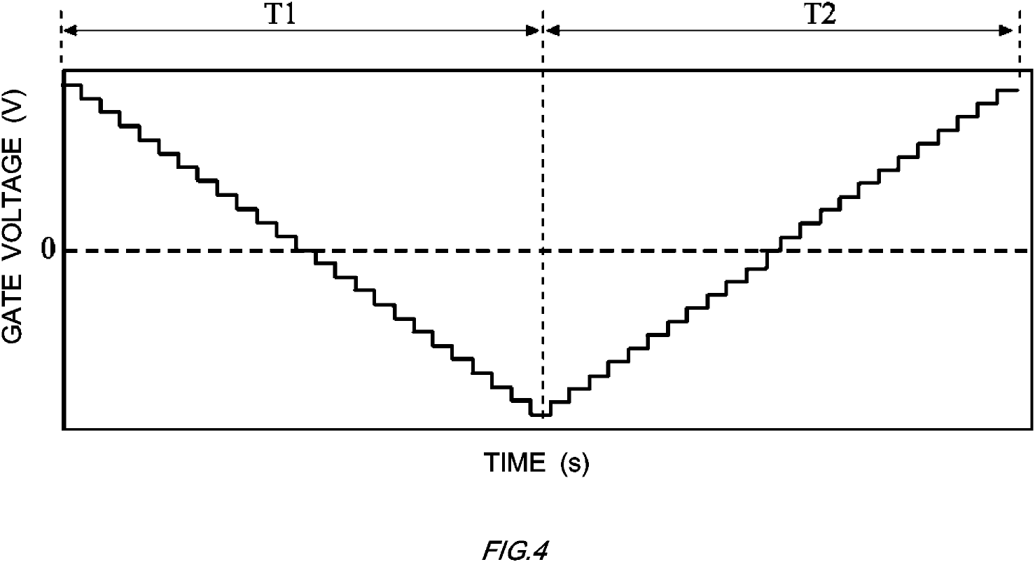

FIG. 4 illustrates an example of a gate voltage waveform when measuring the current-voltage characteristics. In the present example, the gate voltage is changed and swept in a stepped manner. The first characteristics 152 in FIG. 3 are measured by period T1 in FIG. 4, and the second characteristics 162 in FIG. 3 are measured by period T2 in FIG. 4.

By changing the gate voltage in the stepped manner, a transient gate current flows at each step time (that is, the time to maintain one gate voltage). The integrated value of the gate current flowing at each step time is used as the value of the gate current at the gate voltage. Since the integrated value of the transient current is used as the value of the gate current, the gate current increases as the step voltage (that is, the difference in the gate voltage between steps) increases. However, if the step voltage is sufficiently small (for example, 0.1 V or less), the waveform of the current-voltage characteristics hardly fluctuate. Also, as the step time increases, the value of the gate current increases. On the other hand, the absolute value of the gate current may fluctuate with the step time, but the shape of the waveform of the current-voltage characteristics and the hole injection start voltage V_{S} hardly fluctuate. By sweeping the gate voltage as shown in FIG. 4, the current-voltage characteristics (especially the voltage range of the peak waveform) as shown in FIG. 3 can be accurately acquired. Note that, the current-voltage characteristics as shown in FIG. 3 can be measured with the “Keysight B1500A” semiconductor device analyzer from Keysight Technology, Inc., but the measurement apparatus is not limited to this.

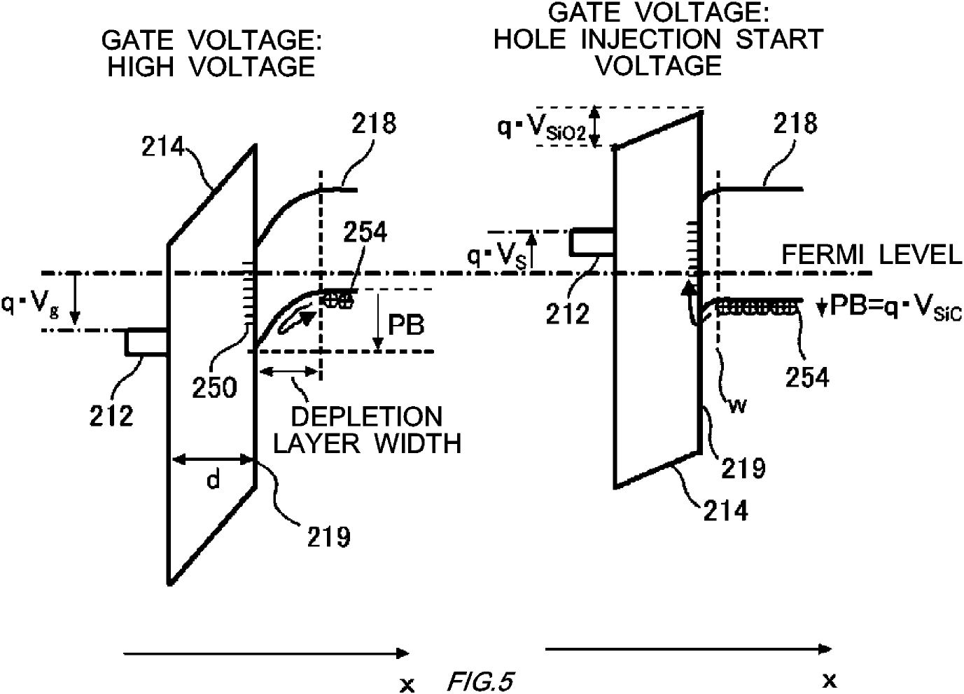

FIG. 5 illustrates the hole injection start voltage V_{S}. FIG. 5 shows the energy bands of the gate electrode 212, the gate insulating film 214 and the channel region 218 when the gate voltage is a relatively high voltage and when the gate voltage is the hole injection start voltage V_{S}.

When the gate voltage is high voltage, the potential barrier PB formed by the depletion layer becomes higher. Therefore, holes 254 in the channel region 218 cannot overcome the potential barrier PB and are not trapped in the hole traps 250 at the interface 219.

As the gate voltage decreases, the depletion layer shrinks and the potential barrier PB becomes smaller. Therefore, the holes 254 overcome the potential barrier PB due to the thermal energy and begin to be trapped in the hole traps 250, and the gate current flows. The gate voltage at this time corresponds to the hole injection start voltage V_{S}.

When the holes 254 are trapped at the interface 219, the potential barrier increases and the gate current decreases due to the electric charges, but if the gate voltage further decreases, the potential barrier decreases again and gate current flows. If the holes 254 are trapped in all hole traps 250, no gate current flows even if the gate voltage further decreases. Therefore, by sweeping the gate voltage as shown in FIG. 4, the current-voltage characteristics as shown in FIG. 3 can be obtained. Note that, actually, a displacement current also exists, but the semiconductor device analyzer does not detect the fast response current.

Note that, as the temperature rises, the thermal energy increases and therefore it becomes easier for the holes 254 to overcome the potential barrier PB, but since the threshold voltage Vth decreases as the temperature rises, the hole injection start voltage does not change much. For example, even if the temperature changes from 25° C. to 102° C., the hole injection start voltage only changes by about 0.8 V. The voltage determination unit 106 may determine the hole injection start voltage based on the current-voltage characteristics under room temperature.

The voltage determination unit 106 may set the off-gate voltage to be lower than 0 V. In this manner, erroneous turning on due to noise and so on can be reduced. Also, the voltage determination unit 106 may set the off-gate voltage to be a voltage lower than the hole injection start voltage V_{S}. In this manner, erroneous turning on due to noise and so on can be further suppressed. Even if the off-gate voltage is lower than the hole injection start voltage V_{S}, if the difference between the off-gate voltage and the hole injection start voltage V_{S} is not so large, fewer holes 254 are trapped in the hole traps 250 and have little effect on the threshold voltage Vth. In the present example, the voltage, at which the amount of holes 254 trapped in the hole traps 250 becomes a substantial amount enough to affect the threshold voltage Vth, is referred to as the effective hole injection start voltage V_{E}.

The voltage determination unit 106 may set the off-gate voltage to a voltage higher than the effective hole injection start voltage V_{E} determined by the equation below.

$${\text{V}}_{\text{E}} {\text{=V}}_{\text{S}} \text{-} \left({\text{V}}_{\text{SiC}} {\text{+V}}_{\text{SiO2}}\right)$$

Here, V_{S} is the hole injection start voltage, V_{SiC} is the voltage applied to the depletion layer of the channel region 218 when the hole injection start voltage V_{S} is applied to the gate electrode 212, that is, with a magnitude of the potential barrier PB in FIG. 5, and V_{SiO2} is the voltage applied to the gate insulating film 214 when the hole injection start voltage V_{S} is applied to the gate electrode 212, or more accurately, with a magnitude of the voltage when no electric charge exists in the oxide film or at the interface. Note that, the effect of the electric charges is included in Vs.

The hole injection start voltage V_{S} can be acquired from the current-voltage characteristics shown in FIG. 3. V_{SiC} may be set as 0.6 V under room temperature as shown in the following reference. The reference is “Slow response in gate current-voltage characteristics of metal-oxide-semiconductor structures on the 4H-SiC (0001/) face”, Naoki Kumagai et al, 2016 Japanese Journal of Applied Physics 55, 054103).

The voltage determination unit 106 may determine V_{SiO2} based on the equation below.

$${\text{V}}_{\text{SiO2}} {\text{=V}}_{\text{SiC}} ⋅ {\text{C}}_{\text{SiC}} / {\text{C}}_{\text{SiO2}}$$

Here, C_{SiC} is the capacitance (C) of the depletion layer formed near the interface 219 in the MOS transistor 200 with the hole injection start voltage V_{S} applied to the gate electrode 212, and C_{SiO2} is the capacitance (C) of the gate insulating film 214.

If the electric field in the channel region 218 is E, the equation below holds.

$$\text{dE} / \text{dx} \text{} \text{=} \text{} \text{ρ} / {\text{ε}}_{\text{SiC}}$$

Here, x is the position in the direction perpendicular to the interface 219, and ε_{SiC} is the permittivity of the channel region 218. Note that, the permittivity (F/cm) is the value obtained by multiplying the vacuum permittivity by the relative permittivity. Also, ρ=q•p, here, q is the elementary electric charge amount (q=1.602× 10⁻¹⁹(C)) and p is the doping concentration (/cm³) in the channel region 218. V_{SiC} is also given by the equation below.

$${\text{V}}_{\text{SiC}} \text{=} \text{ρ} {\text{w}}^{2} / 2 {\text{ε}}_{\text{SiC}} \text{} \text{=0} \text{.6V}$$

Here, w(cm) is the width in the x direction of the depletion layer formed near the interface 219 in the MOS transistor 200 with the hole injection start voltage V_{S} applied to the gate electrode 212.

From Equation 3, the depletion layer width w is given by the equation below.

$$\text{w=} {\left(1.2 ⋅ {\text{ε}}_{\text{SiC}} / \text{ρ}\right)}^{1 / 2}$$

Using the depletion layer width w and the thickness d(cm) of the gate insulating film 214 in the x direction, the respective capacitances are given by the equation below.

$${\text{C}}_{\text{SiC}} \text{=} {\text{ε}}_{\text{SiC}} / \text{w} \text{=} {\left(\text{ρ} ⋅ {\text{ε}}_{\text{SiC}} / 1.2\right)}^{1 / 2}$$

$${\text{C}}_{\text{SiO2}} \text{=} {\text{ε}}_{\text{SiO2}} / \text{d}$$

Here, ε_{SiO2} is the permittivity of the gate insulating film 214. Accordingly, Equation 2 can be transformed as in the equation below.

$${\text{V}}_{\text{SiO2}} \text{=0} \text{.6} ⋅ \text{d} ⋅ {\left(\text{ρ} ⋅ {\text{ε}}_{\text{SiC}} / 1.2\right)}^{1 / 2} / {\text{ε}}_{\text{SiO2}}$$

The voltage determination unit 106 may calculate V_{SiO2} based on d, ρ, ε_{SiC} and ε_{SiO2}. These values may be acquired from the specification of the MOS transistor 200 and so on, or may be actually measured from the MOS transistor 200. Each parameter described in FIG. 5 may use values under room temperature (25° C.).

When the gate voltage below the effective hole injection start voltage V_{E} shown in Equation 1 is applied, the potential barrier disappears, so the hole trapping rate becomes a very fast rate that is determined by the trapping cross section of the trap, and holes begin to be trapped rapidly. On the other hand, at the gate voltage above V_{E}, the hole trapping rate is limited by the potential barrier and the trapping rate is slowed down because of the formation of the potential barrier. Note that, while V_{E} corresponds to the flat band voltage and, in the ideal case, can be calculated from the oxide film thickness channel concentration and so on, it is obtained based on the hole injection start voltage because the value actually differs from the ideal due to electron traps at the interface, fixed electric charges and so on. Note that, this flat band voltage is a transient value before holes are trapped. Accordingly, the flat band voltage is different from the flat band voltage obtained from the CV characteristics because the flat band is negatively shifted due to hole trapping. In the present example, the voltage determination unit 106 sets the voltage larger than the effective hole injection start voltage V_{E} as the off-gate voltage.

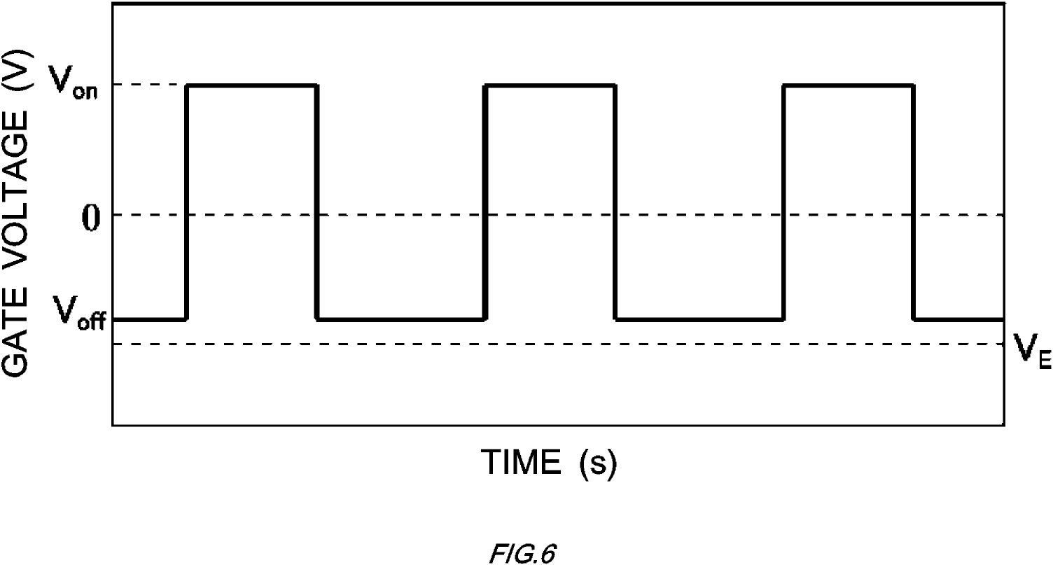

FIG. 6 illustrates an example of the gate voltage applied to the MOS transistor 200. The on-gate voltage applied when turning on the MOS transistor 200 is indicated by Vₒₙ, and the off-gate voltage applied when turning off the MOS transistor 200 is indicated by V_{off}. The voltage determination unit 106 sets the off-gate voltage V_{off} to be a voltage higher than the effective hole injection start voltage V_{E}. In this manner, the fluctuation of the threshold voltage Vth due to hole trapping can be suppressed. The voltage determination unit 106 may set the off-gate voltage V_{off} higher than the effective hole injection start voltage V_{E} by 0.1 V or more, or may set the off-gate voltage V_{off} higher than the effective hole injection start voltage V_{E} by 0.2 V or more.

Also, the voltage determination unit 106 may set the off-gate voltage V_{off} lower than 0 V. In this manner, erroneous turning on due to noise and so on can be suppressed. The voltage determination unit 106 may set the off-gate voltage V_{off} lower than the hole injection start voltage V_{S}. The voltage determination unit 106 may set the off-gate voltage V_{off} lower than -3 V.

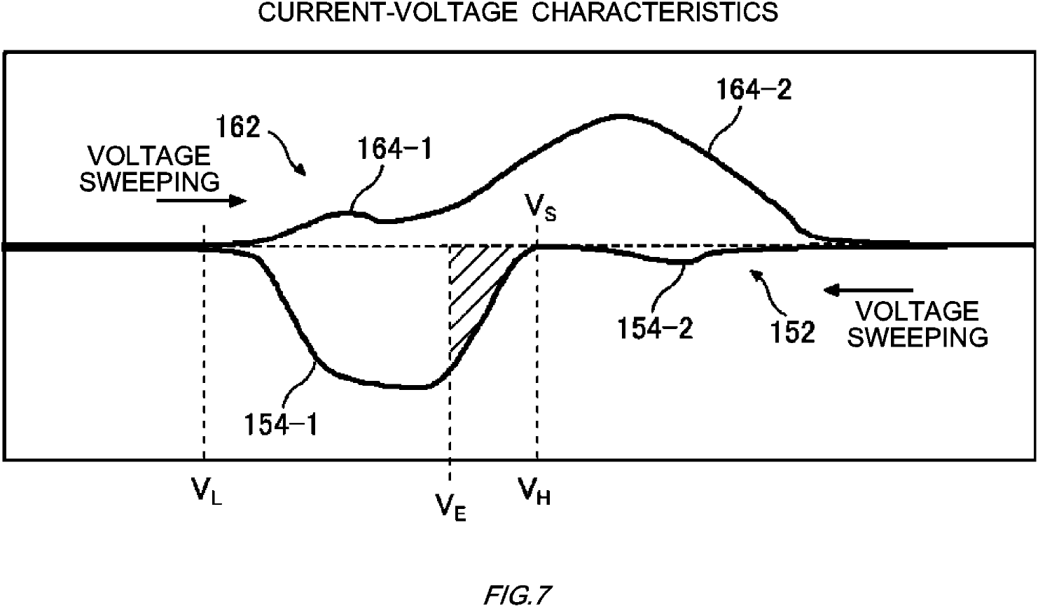

FIG. 7 illustrates another determination method of the effective hole injection start voltage V_{E}. In the present example, a value obtained by partially integrating the gate current of the peak waveform 154-1 from the hole injection start voltage V_{S} to the effective hole injection start voltage V_{E} is used as a partial integrated value (the integrated value of the shaded area in FIG. 7). Also, a value obtained by entirely integrating the gate current of the peak waveform 154-1 (from the hole injection start voltage V_{S} to the voltage V_{L}) is used as the overall integrated value. The voltage determination unit 106 may use the effective hole injection start voltage V_{E} where the partial integrated value becomes ¼ of the overall integrated value. It can be experimentally confirmed that the threshold voltage Vth of MOS transistor 200 does not change much even when holes equivalent to about ¼ of the overall integrated value of the peak waveform 154-1 are trapped.

Note that, the voltage determination unit 106 may correct the effective hole injection start voltage V_{E} according to the working frequency of the MOS transistor 200 during actual use. As the working frequency increases and the one off-time becomes shorter, the amount of holes trapped decreases even when a low off-gate voltage is set. The voltage determination unit 106 may shift the effective hole injection start voltage V_{E} to the lower voltage side as the working frequency is higher.

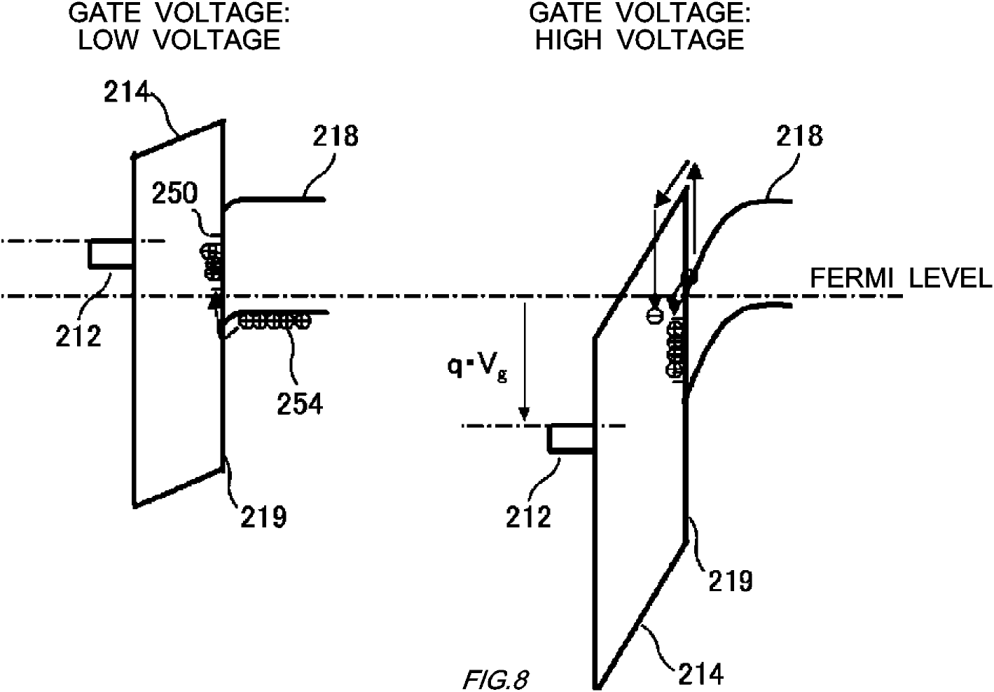

FIG. 8 illustrates fluctuation of the threshold voltage Vth. When the gate voltage is set to be low voltage, the holes 254 are trapped in the hole traps 250. Then, when the gate voltage is set to be a high voltage to form the inversion layer in the channel region 218, the electrons in the inversion layer recombine with the holes trapped at the interface 219. This recombination energy (for example, optical energy of luminescence due to recombination) excites electrons in the inversion layer, which are injected into the gate insulating film 214 by the electric field and trapped in the gate insulating film 214. The trapping of electrons in the gate insulating film 214 shifts the threshold voltage Vth to the higher voltage side.

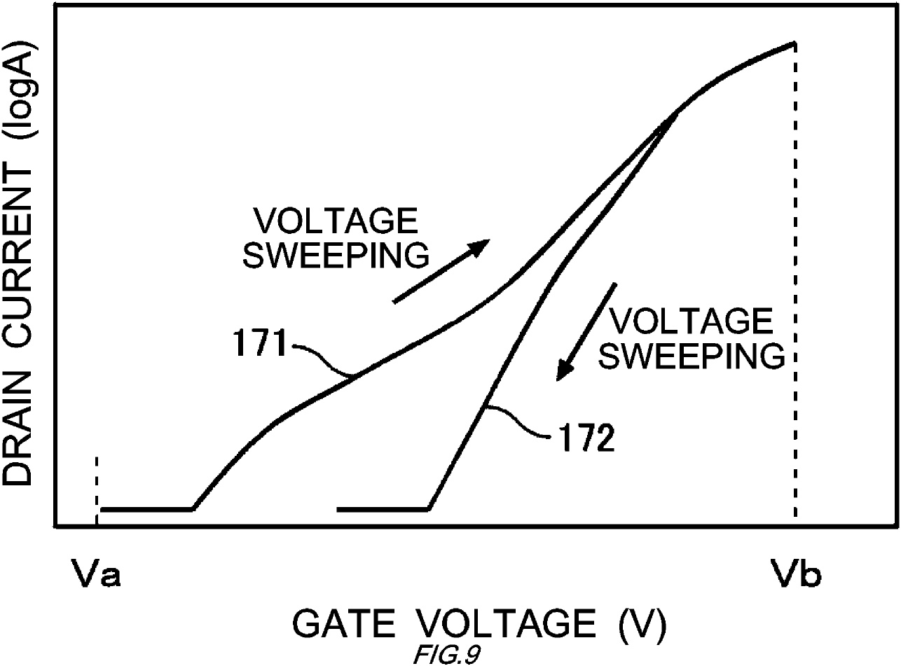

FIG. 9 shows a result of measuring the voltage between the source electrode 204 and the gate electrode 212 and the current flowing between the drain electrode 206 and the source electrode 204 by applying a constant voltage between the source electrode 204 and the drain electrode 206. FIG. 9 is used to illustrate which peak waveform 154 is used to determine the hole injection start voltage when a plurality of peak waveforms 154 are included in the current-voltage characteristics (first characteristics 152). In the present example, the characteristic acquisition unit 104 acquires hysteresis characteristics including characteristics 171 and characteristics 172 for the range of the gate voltage of each peak waveform 154 (for example, for the peak waveform 154-1, at least a part of the range of V_{H} to V_{L}). The characteristic vertical axis in FIG. 9 is on the Log scale, so the flat characteristic indicates the noise level (about 10 pA to 100 pA). If the noise is large, this current level rises and the hysteresis appears small, but it may be judged by the presence or absence of hysteresis.

The characteristics 171 show the relationship between the drain current and the gate voltage when the gate voltage is changed from the lower voltage side to the higher voltage side. Also the characteristics 172 show the relationship between the drain current and the gate voltage when the gate voltage is changed from the higher voltage side to the lower voltage side. In the present example, the characteristic acquisition unit 104 acquires the characteristics 171 when sweeping the gate voltage from the sweep start voltage Va to the fold-back voltage Vb that is larger than the voltage Va, and characteristics 172 when sweeping the gate voltage from the voltage Vb to the voltage Va. The sweep start voltage is, for example, the voltage on the lower voltage side of the voltages at both ends of each peak waveform (for example, V_{L} for the peak waveform 154-1).

When the sweep start voltage Va is larger than the hole injection start voltage V_{S}, the waveforms of characteristics 171 and characteristics 172 become approximately identical. On the other hand, when the sweep start voltage Va is equal to or below the hole injection start voltage V_{S}, the holes are trapped at the interface 219 during at least a part of the period, resulting in that the waveforms of the characteristics 171 and the characteristics 172 become different.

When the current-voltage characteristics (the first characteristics 152) includes a plurality of peak waveforms 154, the voltage determination unit 106 may select any peak waveform 154 based on the hysteresis characteristics (the characteristics 171 and characteristics 172) of each peak waveform 154, and determine the off-gate voltage based on the value of the gate voltage of the selected peak waveform 154 (for example, the hole injection start voltage). The voltage determination unit 106 may select the peak waveform 154 with the largest difference between the gate voltage at which the drain current becomes the initial value in the characteristics 171 and the gate voltage at which the drain current becomes the initial value in the characteristics 172. In this manner, when the plurality of peak waveforms 154 exist, the appropriate peak waveform 154 can be selected to set the off-gate voltage.

The characteristic acquisition unit 104 may acquire luminescence characteristics indicating the luminescence state of the MOS transistor 200 when the gate voltage applied to the gate electrode 212 is changed from the higher voltage side to the lower voltage side. As described in FIG. 5 and so on, when the gate voltage becomes lower than the hole injection start voltage and holes overcome the potential barrier, the holes are trapped at the interface, and when the on-gate voltage is subsequently applied to the gate, electrons in the inversion layer recombine with the holes trapped at the interface 219 and emit light. On the other hand, in the trench-type MOS transistor 200, when the lower sub-regions 201b of the P⁺ type with relatively high concentration is in contact with the gate insulating film 214 like the lower sub-regions 201b of the P⁺ type at the trench bottom in FIG. 2, the peak waveform 154-2 may be observed due to the current when holes are injected into the lower sub-regions 201b of the P⁺ type at the trench bottom, or the current when holes are excited. The higher the concentration of the lower sub-regions 201b of the P⁺ type is, the higher on the high potential side this peak appears. In this case, the voltage at which the normal inversion layer is formed is very high, and no electrons are injected, so luminescence due to recombination of holes and electrons does not occur.

When the current-voltage characteristics include the plurality of peak waveforms 154, the voltage determination unit 106 may select any peak waveform 154 based on the acquired luminescence characteristics, and determine the off-gate voltage based on the value of the gate voltage of the selected peak waveform 154. The voltage determination unit 106 may select the peak waveform 154 where luminescence is occurring. The voltage determination unit 106 may select the peak waveform 154 with the largest luminescence intensity. Also, the hole injection start voltage may be determined directly by the presence or absence of luminescence.

When the current-voltage characteristics include the plurality of peak waveforms 154, the voltage determination unit 106 may select the peak waveform 154 at a lowest on the lower voltage side. Also, when the current-voltage characteristics include the plurality of peak waveforms 154, the voltage determination unit 106 may select the peak waveform 154 with the largest gate current amplitude. This allows selection of the peak waveform 154 with a simple process.

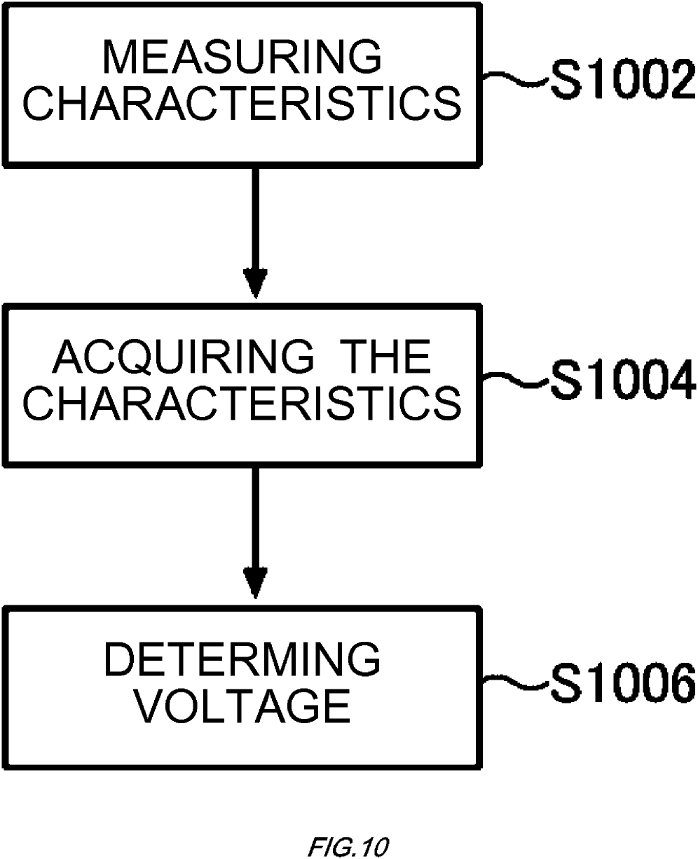

FIG. 10 illustrates a flowchart showing an overview of a gate voltage determination method of the MOS transistor 200. The gate voltage determination method includes measuring characteristics S1002, acquiring the characteristics S1004 and determining a voltage S1006. The process in measuring the characteristics S1002 is similar to the process of the characteristic measurement unit 102 described in FIG. 1 to FIG. 9. The process in acquiring the characteristics S1004 is similar to the process of the characteristic acquisition unit 104 described in FIG. 1 to FIG. 9. The process in determining the voltage S1006 is similar to the process of the voltage determination unit 106 described in FIG. 1 to FIG. 9.

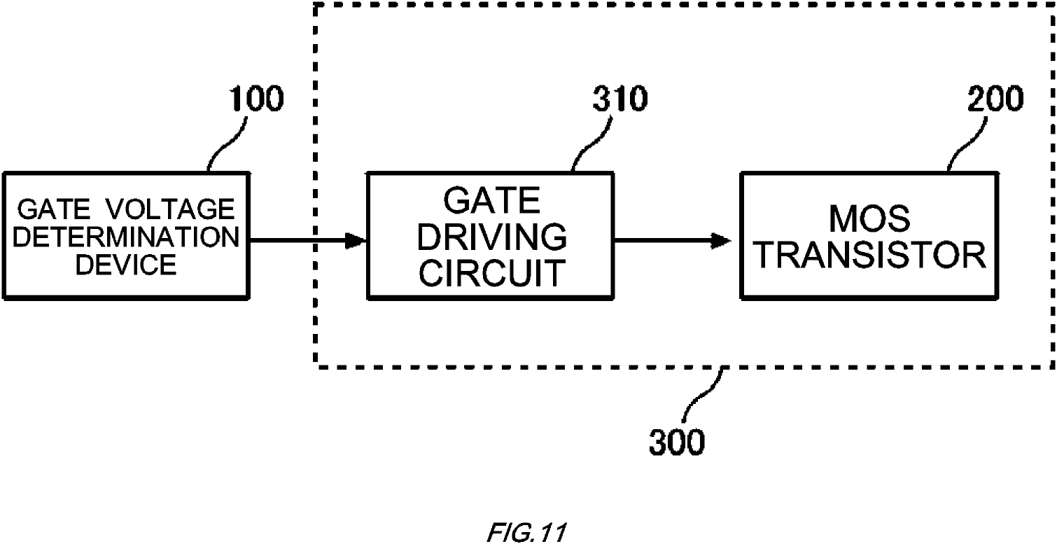

FIG. 11 illustrates a block diagram showing an overview of a semiconductor circuit 300 according to one embodiment of the present invention. The semiconductor circuit 300 includes a gate driving circuit 310 and the MOS transistor 200. The MOS transistor 200 may be, for example, a part of an inverter, but not limited thereto.

The gate driving circuit 310 applies the gate voltage to the gate electrode 212 of the MOS transistor 200, and drives the MOS transistor 200. The gate driving circuit 310 uses the off-gate voltage determined by the gate voltage determination apparatus 100 described in FIG. 1 to FIG. 10 to turn the MOS transistor 200 to the off-state. The gate driving circuit 310 may set the off-gate voltage to be a voltage lower than the hole injection start voltage V_{S}.

While the embodiments of the present invention have been described, the technical scope of the invention is not limited to the above described embodiments. It is apparent to persons skilled in the art that various alterations or improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A gate voltage determination apparatus of a MOS transistor having a gate electrode, a gate insulating film and a channel region, the gate voltage determination apparatus comprising:
a characteristic acquisition unit configured to acquire current-voltage characteristics showing a relationship between a gate current flowing through the gate electrode and a gate voltage when the gate voltage applied to the gate electrode is changed from a higher voltage side to a lower voltage side; and
a voltage determination unit configured to determine, based on a value of the gate voltage at which the gate current shows a peak waveform in the current-voltage characteristics, an off-gate voltage to be applied to the gate electrode when turning off the MOS transistor.

2. The gate voltage determination apparatus according to claim 1, wherein the gate voltage includes gate voltages on both ends of the peak waveform, and the voltage determination unit is configured to determine the off-gate voltage based on a hole injection start voltage that is a voltage on the higher voltage side of the gate voltages.

3. The gate voltage determination apparatus according to claim 2, wherein the voltage determination unit is configured to determine the off-gate voltage to be a voltage lower than the hole injection start voltage.

4. The gate voltage determination apparatus according to claim 3, wherein
the voltage determination unit is configured to set the off-gate voltage to be a voltage higher than an effective hole injection start voltage V_{E} determined by an equation below,
$${\text{V}}_{\text{E}} = {\text{V}}_{\text{S}} \text{-} \left({\text{V}}_{\text{SiC}} + {\text{V}}_{\text{SiO2}}\right)$$
wherein Vₛ is the hole injection start voltage, V_{SiC} is a voltage applied to a depletion layer of the channel region when the hole injection start voltage is applied to the gate electrode, and V_{SiO2} is a magnitude of a voltage applied to the gate insulating film when the hole injection start voltage is applied to the gate electrode.

5. The gate voltage determination apparatus according to claim 3, wherein:
the voltage determination unit is configured to set the off-gate voltage to be a voltage higher than an effective hole injection start voltage; and
the effective hole injection start voltage is voltage, at which a partial integrated value that is a value obtained by partially integrating the gate current of the peak waveform from the hole injection start voltage to an effective hole injection start voltage becomes ¼ of an overall integrated value obtained by entirely integrating the gate current of the peak waveform.

6. The gate voltage determination apparatus according to claim 1, wherein:
the peak waveform includes a plurality of peak waveforms, and the characteristic acquisition unit is configured to acquire hysteresis characteristics, in a range of the gate voltage of each of the plurality of peak waveforms, including a relationship between a drain current and the gate voltage when the gate voltage is changed from the higher voltage side to the lower voltage side, and a relationship between the drain current and the gate voltage when the gate voltage is changed from the lower voltage side to the higher voltage side; and
when the current-voltage characteristics include the plurality of peak waveforms, the voltage determination unit is configured to select any of the plurality of peak waveforms based on the hysteresis characteristics, and determine the off-gate voltage based on the value of the gate voltage of the peak waveform that is selected.

7. The gate voltage determination apparatus according to claim 1, wherein:
the characteristic acquisition unit is configured to further acquire luminescence characteristics showing a luminescence state of the MOS transistor when the gate voltage applied to the gate electrode is changed from the higher voltage side to the lower voltage side; and
the peak waveform includes a plurality of peak waveforms, and when the current-voltage characteristics include the plurality of peak waveforms, the voltage determination unit is configured to select any of the plurality of peak waveforms based on the luminescence characteristics, and determine the off-gate voltage based on the value of the gate voltage of the peak waveform that is selected.

8. The gate voltage determination apparatus according to claim 1, wherein the peak waveform includes a plurality of peak waveforms, and when the current-voltage characteristics include the plurality of peak waveforms, the voltage determination unit is configured to select the peak waveform with a largest amplitude, and determine the off-gate voltage based on the value of the gate voltage of the peak waveform that is selected.

9. The gate voltage determination apparatus according to claim 1, wherein the peak waveform includes a plurality of peak waveforms, and when the current-voltage characteristics include the plurality of peak waveforms, the voltage determination unit is configured to select the peak waveform at a lowest on the lower voltage side, and determine the off-gate voltage based on the value of the gate voltage of the peak waveform that is selected.

10. A gate voltage determination method of a MOS transistor having a gate electrode, a gate insulating film and a channel region, the gate voltage determination method comprising:
acquiring current-voltage characteristics showing a relationship between a gate current flowing through the gate electrodes and a gate voltage when the gate voltage applied to the gate electrode is changed from a higher voltage side to a lower voltage side; and
determining, based on a value of the gate voltage at which the gate current shows a peak waveform in the current-voltage characteristics, an off-gate voltage to be applied to the gate electrode when turning off the MOS transistor.

11. A gate driving circuit configured to apply a gate voltage to a MOS transistor having a gate electrode, a gate insulating film and a channel region, wherein the gate voltage includes gate voltages on both ends of a peak waveform of a gate current in current-voltage characteristics showing a relationship between the gate current flowing through the gate electrodes and the gate voltage when the gate voltage applied to the gate electrode is changed from the higher voltage side to a lower voltage side, the gate driving circuit is configured to
set an off-gate voltage for turning off the MOS transistor to voltage lower than a hole injection start voltage on the higher voltage side of the gate voltages.

12. A semiconductor circuit comprising:
a MOS transistor; and
the gate driving circuit according to claim 11, configured to apply a gate voltage to the MOS transistor.

13. The gate voltage determination apparatus according to claim 2, wherein:
the peak waveform includes a plurality of peak waveforms, and the characteristic acquisition unit is configured to acquire hysteresis characteristics, in a range of the gate voltage of each of the plurality of peak waveforms, including a relationship between a drain current and the gate voltage when the gate voltage is changed from the higher voltage side to the lower voltage side, and a relationship between the drain current and the gate voltage when the gate voltage is changed from the lower voltage side to the higher voltage side; and
when the current-voltage characteristics include the plurality of peak waveforms, the voltage determination unit is configured to select any of the plurality of peak waveforms based on the hysteresis characteristics, and determine the off-gate voltage based on the value of the gate voltage of the peak waveform that is selected.

14. The gate voltage determination apparatus according to claim 3, wherein:
the peak waveform includes a plurality of peak waveforms, and the characteristic acquisition unit is configured to acquire hysteresis characteristics, in a range of the gate voltage of each of the plurality of peak waveforms, including a relationship between a drain current and the gate voltage when the gate voltage is changed from the higher voltage side to the lower voltage side, and a relationship between the drain current and the gate voltage when the gate voltage is changed from the lower voltage side to the higher voltage side; and
when the current-voltage characteristics include the plurality of peak waveforms, the voltage determination unit is configured to select any of the plurality of peak waveforms based on the hysteresis characteristics, and determine the off-gate voltage based on the value of the gate voltage of the peak waveform that is selected.

15. The gate voltage determination apparatus according to claim 4, wherein:
the peak waveform includes a plurality of peak waveforms, and the characteristic acquisition unit is configured to acquire hysteresis characteristics, in a range of the gate voltage of each of the plurality of peak waveforms, including a relationship between a drain current and the gate voltage when the gate voltage is changed from the higher voltage side to the lower voltage side, and a relationship between the drain current and the gate voltage when the gate voltage is changed from the lower voltage side to the higher voltage side; and
when the current-voltage characteristics include the plurality of peak waveforms, the voltage determination unit is configured to select any of the plurality of peak waveforms based on the hysteresis characteristics, and determine the off-gate voltage based on the value of the gate voltage of the peak waveform that is selected.

16. The gate voltage determination apparatus according to claim 5, wherein:
the peak waveform includes a plurality of peak waveforms, and the characteristic acquisition unit is configured to acquire hysteresis characteristics, in a range of the gate voltage of each of the plurality of peak waveforms, including a relationship between a drain current and the gate voltage when the gate voltage is changed from the higher voltage side to the lower voltage side, and a relationship between the drain current and the gate voltage when the gate voltage is changed from the lower voltage side to the higher voltage side; and
when the current-voltage characteristics include the plurality of peak waveforms, the voltage determination unit is configured to select any of the plurality of peak waveforms based on the hysteresis characteristics, and determine the off-gate voltage based on the value of the gate voltage of the peak waveform that is selected.

17. The gate voltage determination apparatus according to claim 2, wherein:
the characteristic acquisition unit is configured to further acquire luminescence characteristics showing a luminescence state of the MOS transistor when the gate voltage applied to the gate electrode is changed from the higher voltage side to the lower voltage side; and
the peak waveform includes a plurality of peak waveforms, and when the current-voltage characteristics include the plurality of peak waveforms, the voltage determination unit is configured to select any of the plurality of peak waveforms based on the luminescence characteristics, and determine the off-gate voltage based on the value of the gate voltage of the peak waveform that is selected.

18. The gate voltage determination apparatus according to claim 3, wherein:
the characteristic acquisition unit is configured to further acquire luminescence characteristics showing a luminescence state of the MOS transistor when the gate voltage applied to the gate electrode is changed from the higher voltage side to the lower voltage side; and
the peak waveform includes a plurality of peak waveforms, and when the current-voltage characteristics include the plurality of peak waveforms, the voltage determination unit is configured to select any of the plurality of peak waveforms based on the luminescence characteristics, and determine the off-gate voltage based on the value of the gate voltage of the peak waveform that is selected.

19. The gate voltage determination apparatus according to claim 4, wherein:
the characteristic acquisition unit is configured to further acquire luminescence characteristics showing a luminescence state of the MOS transistor when the gate voltage applied to the gate electrode is changed from the higher voltage side to the lower voltage side; and
the peak waveform includes a plurality of peak waveforms, and when the current-voltage characteristics include the plurality of peak waveforms, the voltage determination unit is configured to select any of the plurality of peak waveforms based on the luminescence characteristics, and determine the off-gate voltage based on the value of the gate voltage of the peak waveform that is selected.

20. The gate voltage determination apparatus according to claim 5, wherein:
the characteristic acquisition unit is configured to further acquire luminescence characteristics showing a luminescence state of the MOS transistor when the gate voltage applied to the gate electrode is changed from the higher voltage side to the lower voltage side; and
the peak waveform includes a plurality of peak waveforms, and when the current-voltage characteristics include the plurality of peak waveforms, the voltage determination unit is configured to select any of the plurality of peak waveforms based on the luminescence characteristics, and determine the off-gate voltage based on the value of the gate voltage of the peak waveform that is selected.
